(19) United States
(12) Patent Application Publication
(10) Pub. No.: US 2009/0224257 A1
(43) Pub. Date: Sep. 10, 2009

(54) THIN FILM TRANSISTOR PANEL AND MANUFACTURING METHOD OF THE SAME

(75) Inventors: Hong-Kee CHIN, Suwon-si (KR); Shin-Il CHOI, Seoul (KR); Sang-Gab KIM, Seoul (KR); Min-Seok OH, Yongin-si (KR); Yu-Gwang JEONG, Yongin-si (KR); Seung-Ha CHOI, Siheung-si (KR); Dong-Ju YANG, Seoul (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/390,076

(22) Filed: Feb. 20, 2009

(30) Foreign Application Priority Data
Mar. 7, 2008 (KR) 10-2008-0021667

(51) Int. Cl. H01L 33/00

(52) U.S. Cl. 257/72; 438/34; 257/E33.053

(57) ABSTRACT

A thin film transistor array panel includes a gate line formed on a substrate and including a gate electrode, a semiconductor layer formed on a surface of the substrate having the gate line, a data line formed on the semiconductor layer, insulatedly intersecting the gate line, and including a source electrode disposed on the gate electrode, a drain electrode separated from the source electrode by a channel, disposed on the gate electrode, and formed from the same layer as the data line, a passivation layer formed on the data line and the drain electrode and having a first contact hole exposing the drain electrode, and a pixel electrode formed on the passivation layer and contacting the drain electrode through the first contact hole. The data line and the drain electrode may include a first layer and a second layer formed on the first layer, a planar edge of the first layer protrudes from a planar edge of the second layer, and the first layer is formed by dry-etching and the second layer is formed by wet-etching.

This application claims priority to Korean Patent Application No. 10-2008-0021667 filed on Mar. 7, 2008, and all the benefits accruing therefrom under 35 U.S.C. 119, the contents of which are incorporated herein by reference in their entirety.

### BACKGROUND OF THE INVENTION

(a) Field of the Invention

The present invention relates to a thin film transistor array panel and a manufacturing method thereof.

(b) Description of the Related Art

Flat panel displays such as a liquid crystal display and an organic light emitting device include pairs of field generating electrodes having electro-optical active layers interposed between each pair of field generating electrode. The liquid crystal display includes a liquid crystal layer as an electro-optical active layer, and an organic light emitting device (“LED”) includes an organic emission layer as an electro-optical active layer.

A pixel electrode, which is one of the electrodes in a pair of field generating electrodes, can be connected to a switching element which transmits signals to the pixel electrode, and the electro-optical active layer converts the electrical signals to optical signals to display images.

A thin film transistor (“TFT”) having three terminals is used for the switching element in the flat panel display, and a plurality of signal lines including gate lines and data lines are also provided on the flat panel display. The gate lines transmit signals for controlling the TFTs and the data lines transmit signals applied to the pixel electrodes.

Meanwhile, as the lengths of the signal lines increase along with the size of the LCD, which increases resistance in these lines, and a signal delay or a voltage drop occurs due to the increased resistance. Wiring made of a material having low resistivity, such as copper (Cu), is very useful for reducing this phenomenon.

When a signal line made of copper is in direct contact with a semiconductor layer of a thin film transistor, copper atoms diffuse into the semiconductor layer, which can cause performance of the thin film transistor to deteriorate. In addition, use of a lower blocking layer for preventing the diffusion of the copper atoms, and which is formed under the signal line made of copper, presents an added difficulty where it is difficult to wet-etch or dry-etch the lower blocking layer and the signal line made of copper simultaneously, so that the blocking layer and the signal line may not form simultaneously.

### BRIEF SUMMARY OF THE INVENTION

The problems of the prior art as discussed hereinabove are overcome by a signal line made of copper which provides a display device having a signal line including copper, and by a manufacturing method thereof.

In an embodiment, a thin film transistor array panel includes: a gate line formed on a substrate and including a gate electrode; a semiconductor layer formed on the gate electrode; a data line formed on the semiconductor layer, insulatedly intersecting the gate line (where insulatedly intersecting means that an insulating layer separates the data line and the gate line at the point of intersection), and including a source electrode disposed on the gate electrode, a drain electrode separated from the source electrode by a channel exposing a portion of the semiconductor layer, and disposed on the gate electrode and formed from the same layer as the data line (i.e., formed simultaneously from a common layer); a passivation layer formed on the data line and the drain electrode and having a first contact hole exposing a portion of the drain electrode; and a pixel electrode formed on the passivation layer and contacting the drain electrode through the first contact hole. The data line and the drain electrode include a first layer and a second layer formed on the first layer where a planar edge of the first layers of the data line and the drain electrode protrude from a corresponding planar edge of the second layers of the data line and the drain electrode (i.e., where the first layer has a similar shape but a larger surface area than the second layer).

The second layers of the data line and the drain electrode may include copper.

The protruding portion of the first layer of the data line and the drain electrode may have a width of about 0.4 μm to about 0.9 μm.

A gap across the channel between the second layers of the source electrode and the drain electrode may be larger than a gap across the channel between the first layers of the source electrode and the drain electrode.

The semiconductor layer may have substantially the same planar shape (in the x-y plane of the substrate) as that of the data line and the drain electrode except that the semiconductor layer is not bisected by the channel.

The first layer of the data line may have a double-layered structure having a lower layer including titanium (Ti) and an upper layer including titanium nitride (“TiNx”) and formed on the lower layer.

The thin film transistor array panel may further include a storage electrode line separate from the gate line and extending parallel to the gate line, and the storage electrode line may overlap the pixel electrode (i.e., when viewed along the z axis perpendicular to the x-y plane of the substrate) to form a storage capacitor.

The thin film transistor array panel may further include a storage electrode formed from the same layer(s) as the data line, and the passivation layer may have a second contact hole exposing a portion of the storage electrode line, and the storage electrode may be connected to the pixel electrode through the second contact hole and overlaps the storage electrode line to form a storage capacitor.

The storage electrode line may include a first portion overlapping the storage electrode and a second portion not overlapping the storage electrode, and the first portion has a larger surface area (in the x-y plane) than that of the second portion.

The first layer of the data line and the drain electrode may include titanium (Ti) titanium nitride (TiNx), or both Ti and TiNx.

The first layer of the data line and the drain electrode may be formed by dry-etching, and the second layer of the data line and the drain electrode may be formed by wet-etching.

In another embodiment, a manufacturing method of a thin film transistor array panel includes forming a gate line including a gate electrode on a substrate; forming a gate insulating layer on the substrate having the gate line; forming a semiconductor layer on the gate insulating layer; forming a data line insulatedly intersecting the gate line and including a source electrode and a drain electrode, the drain electrode separated from the source electrode by a channel exposing a portion of the semiconductor layer; forming a passivation layer over the source electrode and drain electrode, the passivation layer having a first contact hole exposing a portion of the drain electrode; and forming a pixel electrode on the passivation layer, the pixel electrode contacting the drain electrode through the first contact hole on the passivation layer, where the data line and the drain electrode may each include a first layer and a second layer formed on the first layer, and the first layer may be formed by dry-etching, and the second layer formed by wet-etching.

A planar edge of the first layers of the data line and the drain electrode may protrude from beneath a corresponding planar edge of the second layers of the data line and the drain electrode.

The protruding portion of the first layer of the data line and the drain electrode may have a width of about 0.4 μm to about 0.9 μm.

The forming of the data line and the drain electrode may include depositing a first metal layer on the semiconductor layer, depositing a second metal layer on the first metal layer, forming a photosensitive layer pattern on the second metal layer, forming the second layer of the data line and the drain electrode by wet-etching the second metal layer with the photosensitive layer pattern as an etch mask, and forming the first layer of the data line and the drain electrode by dry-etching the first metal layer with the photosensitive layer pattern and the second layer as a mask.

The second layer of the data line and the drain electrode may include copper.

The first layer of the data line and the drain electrode may include titanium (Ti) titanium nitride (TiNx), or both Ti and TiNx.

The first layer of the data line and the drain electrode may have a double-layered structure having a lower layer including titanium (Ti) and an upper layer including titanium nitride (TiNx) and formed on the lower layer.

The forming of the semiconductor layer and the forming of the data line and the drain electrode may be performed simultaneously, where the forming of the semiconductor layer, the data line, and drain electrode may include depositing a semiconductor film on the gate insulating layer, depositing a first metal layer on the semiconductor film; depositing a second metal layer on the first metal layer; forming a first photosensitive layer pattern on the second metal layer, patterning the second metal layer by wet-etching the second metal layer with the first photosensitive layer pattern as a mask, patterning the first metal layer and forming the semiconductor layer by dry etching the first metal layer and the semiconductor film using the patterned second metal layer as a mask, ashing a portion of the first photosensitive layer pattern to form a second photosensitive layer pattern exposing the channel region, wet-etching the second metal layer with the second photosensitive layer pattern as a mask to remove the second metal layer on the channel regions to form the second layer of the data line and the drain electrode, dry-etching the first metal layer with the second photosensitive layer pattern and the second layer of the data line and the drain electrode as a mask to remove the first metal layer on the channel portions to form the first layer of the data line and the drain electrode, and removing the second photosensitive layer pattern by ashing.

### BRIEF DESCRIPTION OF THE DRAWINGS

FIG. 1 is a layout view of an exemplary thin film transistor array panel according to an embodiment.

FIG. 2 is a sectional view of the exemplary thin film transistor array panel shown in FIG. 1 taken along the lines II-II′.

FIG. 3A to FIG. 3H are sectional views of the exemplary thin film transistor array panel shown in FIG. 1 and FIG. 2 in intermediate steps of a manufacturing method thereof according to an embodiment.

FIG. 4 is a layout view of an exemplary thin film transistor array panel according to another embodiment.

FIG. 5 is a layout view of an exemplary thin film transistor array panel according to another embodiment.

FIG. 6 is a sectional view of the exemplary thin film transistor array panel shown in FIG. 5 taken along the lines VI-VI′.

FIG. 7A to FIG. 7G are sectional views of the exemplary thin film transistor array panel shown in FIG. 5 and FIG. 6 in intermediate steps of a manufacturing method thereof according to an embodiment.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” or “disposed on” another element, it can be directly on the other element or intervening elements may also be present. In contrast, when an element is referred to as being “directly on” another element, there are no intervening elements present.

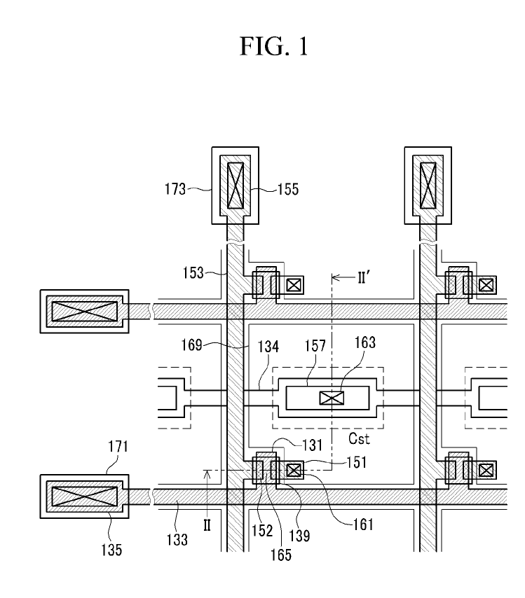

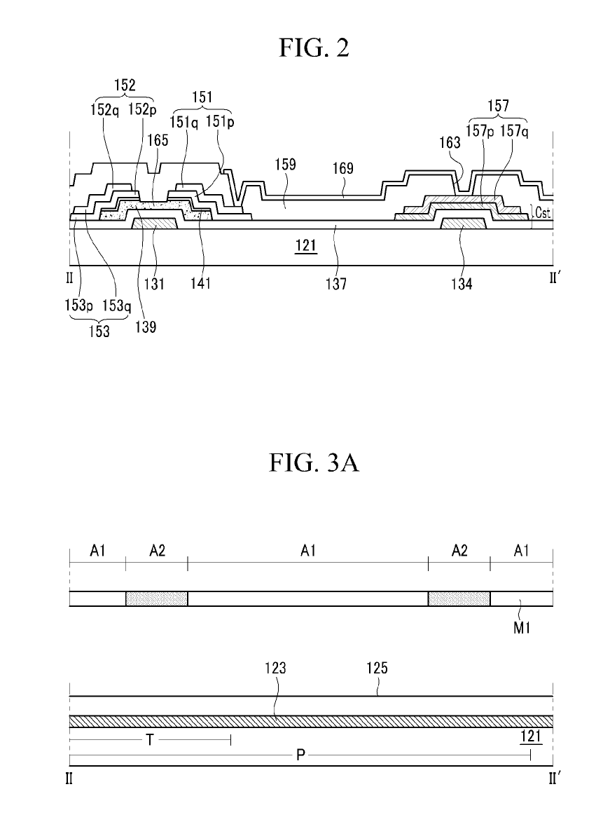

First, a thin film transistor (TFT) array panel according to an embodiment will be described in detail with reference to FIG. 1 and FIG. 2.

FIG. 1 is a layout view of a thin film transistor array panel according to an embodiment, and FIG. 2 is a sectional view of the thin film transistor array panel shown in FIG. 1 taken along the lines II-II′.

A plurality of gate lines 133 and a plurality of storage electrode lines 134 are formed on a surface of an insulating substrate 121 made of a material such as transparent glass or plastic.

The gate lines 133 transmit gate signals and extend substantially in a transverse direction (i.e., along the x-y plane of the insulating substrate 121). Each of the gate lines 133 includes a plurality of gate electrodes 131 projecting upward (i.e., along the z-axis perpendicular to the plane of the insulating substrate 121) and a gate pad 135 having a large area for contact with another layer or an external driving circuit. The gate pad 135 is connected to an auxiliary gate pad 171 disposed on a surface of the gate pad 135 opposite the insulating substrate 121 and made of a transparent conductive layer such as indium-tin-oxide (“ITO”). The auxiliary gate pad 171 improves the contact characteristic between the gate pad 135 and an external driving circuit, and protects the gate pad 135. A gate driving circuit (not shown) for generating the gate signals may be mounted on a flexible printed circuit (“FPC”) film (not shown), which may be attached to the substrate 121, directly mounted on the substrate 121, or integrated with the substrate 121. The gate lines 133 may extend to be connected to a driving circuit that may be integrated with the substrate 121.

The storage electrode lines 134 are supplied with a predetermined voltage, and each of the storage electrode lines 134 extends substantially parallel to the gate line 133 and is disposed between two adjacent gate lines 133 on a surface of the insulating substrate 121. However, the storage electrode lines 134 may have various shapes and arrangements.

The gate lines 133 and the storage electrode lines 134 may be made of an Al-containing metal such as Al or an Al alloy, an Ag-containing metal such as Ag or an Ag alloy, a Cu-containing metal such as Cu or a Cu alloy, an Mo-containing metal such as Mo or an Mo alloy, Cr, Ta, or Ti. Alternatively, or in addition, the gate lines 133 and storage electrode lines 134 may have a multi-layered structure including two layered conductive films (not shown) having different physical characteristics. One of the two films may comprise a low resistivity metal including Al containing metal, Ag containing metal, and Cu containing metal for reducing signal delay and/or voltage drop. The gate lines 133 and the storage electrode lines 134 may be made of various metals or conductors.

A gate insulating layer 137 made of a silicon nitride (SiNx) or a silicon oxide (SiOx) is formed on the surface of the insulating substrate 121 having the gate lines 133 and the storage electrode lines 134.

A plurality of semiconductor layers 139 that may be made of hydrogenated amorphous silicon (abbreviated as “a-Si”) or polysilicon are formed on the gate insulating layer 137. A plurality of ohmic contact layers 141 (see FIG. 2) are formed on a surface of the semiconductor layers 139 opposite gate insulating layer 137. The ohmic contact layers 141 may be made of n+ hydrogenated a-Si heavily doped with an n-type impurity such as phosphorous, or may be made of silicide.

A plurality of data lines 153, a plurality of drain electrodes 151, and a plurality of storage electrodes 157 are formed on surfaces of the ohmic contact layers 141 (opposite the semiconductor layers 139), and the gate insulating layer 137 opposite the insulating substrate 121.

The data lines 153 transmit data signals and extend substantially in the longitudinal direction relative to the gate lines 133 (i.e., perpendicular to the transverse-oriented gate lines 133, in the x-y plane of the substrate), to intersect the gate lines 133. Each of the data lines 153 includes a plurality of source electrodes 152 projecting toward the gate electrodes 131 (parallel to the gate lines 133), and a data pad 155 having a large area for contact with another layer or an external driving circuit. The data pads 155 are connected to an auxiliary data pad 173 disposed on a surface of the data pad 155 and made of a transparent conductive layer such as ITO. The auxiliary data pad 173 improves the contact characteristic between the data pad 155 and an external driving circuit, and protects the data pad 155. A data driving circuit (not shown) for generating the data signals may be mounted on an FPC film (not shown), which may be attached to the substrate 121, directly mounted on the substrate 121, or integrated with the substrate 121. The data lines 153 may extend to be connected to a driving circuit that may be integrated with the substrate 121.

The drain electrodes 151 are separated from the data lines 153 and the source electrodes 152 by channels 165, and are disposed opposite each other (in the x-y plane of the substrate) across the channels 165, and are disposed on surfaces of the ohmic contact layers 141 opposite the gate electrodes 131.

A gate electrode 131, a source electrode 152, and a drain electrode 151 along with a semiconductor layer 139 thus form a thin film transistor (TFT) with a channel 165 formed in the semiconductor layer 139 disposed between the source electrode 152 and the drain electrode 151.

The data lines 153 and the drain electrodes 151 each have a dual-layered structure including a lower layer 153p and 151p and an upper layer 153q and 151q, respectively. The lower layer 153p and 151p may be made of titanium (Ti) or titanium nitride (TiNx), and the upper layer 153q and 151q may be made of copper (Cu). The lower layers 153p and 151p function as barrier layers for blocking the diffusion of the copper atoms of the upper layers 153q and 151q into e.g., the ohmic contact layers 141 and gate insulating layer 137. Here, the lower layer 153p and 151p of the data lines 153 and the drain electrodes 151 may have a double-layered structure having a lower layer made of titanium (Ti) and an upper layer made of titanium nitride (TiNx).

In the thin film transistor array panel, the lower layer 153p and 151p of the data lines 153 and the drain electrodes 151 respectively may be formed by dry-etching a precursor lower metal layer, and the upper layer 153q and 151q of the data lines 153 and the drain electrodes 151 respectively may be formed by wet-etching a precursor upper metal layer.

In general, the dry-etching process is an anisotropic process, while the wet-etching process is an isotropic process. Accordingly, while a metal layer formed by dry-etching may have the same planar shape as a corresponding etching mask used in the dry-etching, a metal layer formed by wet-etching may have a narrower planar shape than that of an etching mask used in wet-etching. In the thin film transistor array panel according to an embodiment of the present invention, the lower layers 153p and 151p of the data lines 153 and the drain electrodes 151 are formed by dry-etching and the upper layers 153q and 151q of the data lines 153 and the drain electrodes 151 are formed by wet-etching, so that planar edges of the lower layer 153p and 151p have a protruding portion protruding more than planar edges of the upper layer 153q and 151q.

In the thin film transistor array panel, the protruding portion of the lower layer 153p and 151p (i.e., the portion that extends from beneath the upper layers 153q and 151q) may have a width of about 0.4 μm to about 0.9 μm, and more specifically about 0.59 μm to about 0.85 μm.

The ohmic contact layers 141 are interposed only between the underlying semiconductor layers 139 and the overlying data lines 153, source electrodes 152, and drain electrodes 151 thereon and have substantially the same shape as the region of overlap between the semiconductor layers 139 and the data lines 153, source electrodes 152, and drain electrodes 151, where the ohmic contact layers 140 reduce contact resistance between the overlapping layers.

A passivation layer 159 is formed on a surface of the data lines 153, the drain electrodes 151, and the exposed portions of the semiconductor layers 139, opposite the insulating substrate 121. The passivation layer 159 may be made of an inorganic or organic insulator, and it may have a flat top (i.e., planarized) surface opposite the insulating substrate 121. Examples of an inorganic insulator include silicon nitride and silicon oxide. An organic insulator may have photosensitivity and a dielectric constant of less than about 4.0. The passivation layer 159 may include (not shown) a lower film of an inorganic insulator and an upper film of an organic insulator such that the excellent insulating characteristics of the organic insulator are present while the exposed portions of the semiconductor layers 139 are prevented from being damaged by the organic insulator.

The passivation layer 159 has a plurality of contact holes 161 and 163 exposing portions of the drain electrodes 151 and the storage electrodes 157, respectively. While not shown, the passivation layer 159 also has a plurality of contact holes exposing portions of the gate pads 135 and the data pads 155, respectively, and the gate pads 135 and the data pads 155 are connected to the auxiliary gate pads 171 and the auxiliary data pads 173 through the contact holes.

A plurality of pixel electrodes 169 are formed on a surface of the passivation layer 159 opposite the gate insulating layer 139, and the pixel electrodes 169 are connected to the drain electrodes 151 and the storage electrodes 157 through the contact holes 161 and 163, respectively. The pixel electrodes 169 may be made of a transparent conductor such as ITO or IZO, or a reflective conductor such as for example Ag, Al, Cr, or alloys thereof.

The pixel electrodes 169 are physically and electrically connected to the drain electrodes 151 through the contact holes 161 such that the pixel electrodes 169 receive data voltages from the drain electrodes 151. The pixel electrodes 169 supplied with the data voltages generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. A pixel electrode 169 and the common electrode form a capacitor referred to as a “liquid crystal capacitor,” which stores applied voltages after the TFT turns off.

A pixel electrode 169 and a storage electrode 157 connected thereto through the contact hole 163 overlap the storage electrode line 134. The pixel electrode 169 and the storage electrode 157 electrically connected thereto and the storage electrode line 134 form an additional capacitor referred to as a “storage capacitor” (abbreviated “Cst” in FIGS. 1, 2, 4 and 5) which enhances the voltage storing capacity of the liquid crystal capacitor.

As described above, the thin film transistor array panel includes the data lines 153 and drain electrodes 151 having a double-layered structure including the lower layer 153p and 151p and the upper layer 153q and 151q. The lower layer 153p and 151p may be made of a titanium-containing material such as titanium (Ti) or titanium nitride (TiNx), and the upper layer 153q and 151q may be made of copper (Cu). The lower layer 153p and 151p functions as a barrier layer for blocking the diffusion of copper of the upper layer 153q and 151q. Accordingly, performance degradation of the thin film transistor caused by the diffusion of copper may be prevented by the presence of the lower layers 153p and 151p.

In addition, the lower layer 153p and 151p may be formed by dry-etching and the upper layer 153q and 151q may be formed by wet-etching, each of an appropriate metal precursor layer, to allow the lower layer 153p and 151p and the upper layer 153q and 151q to be readily patterned.

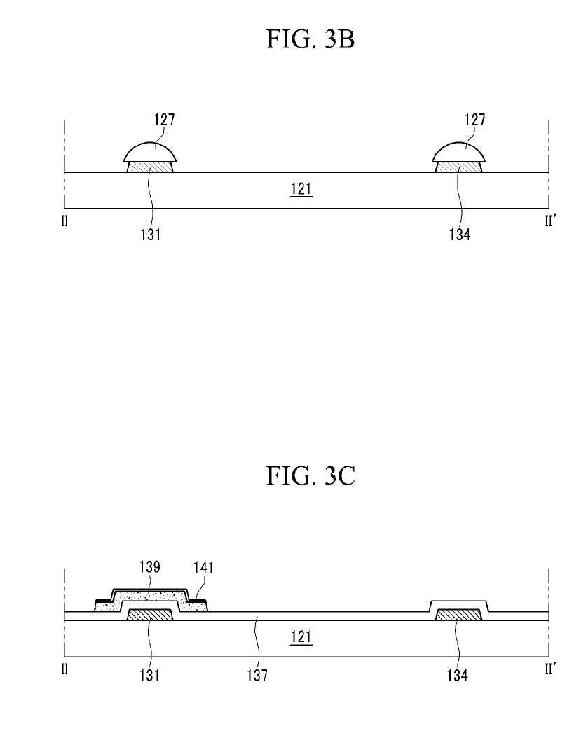

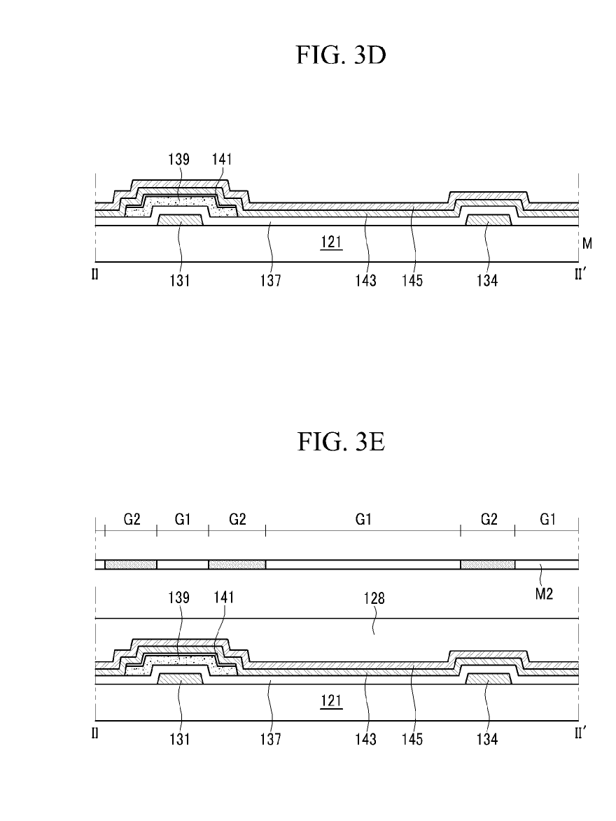

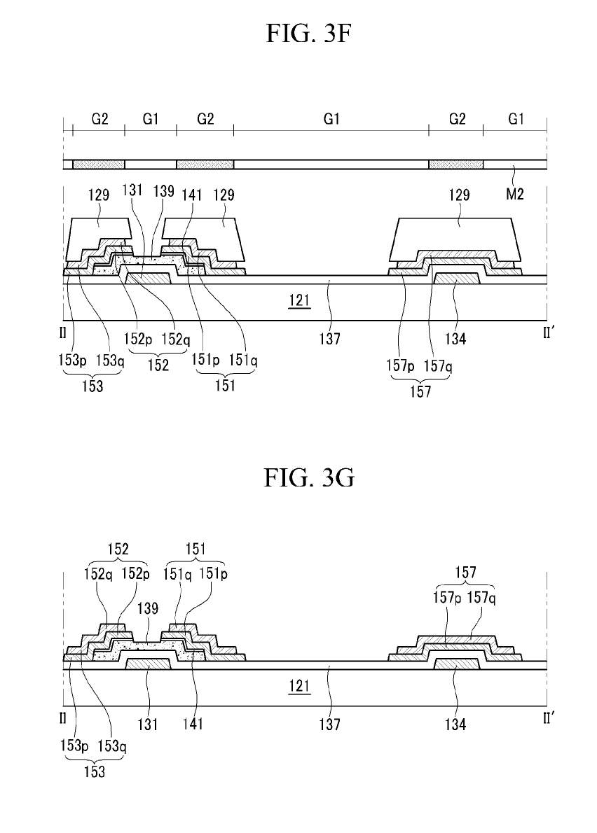

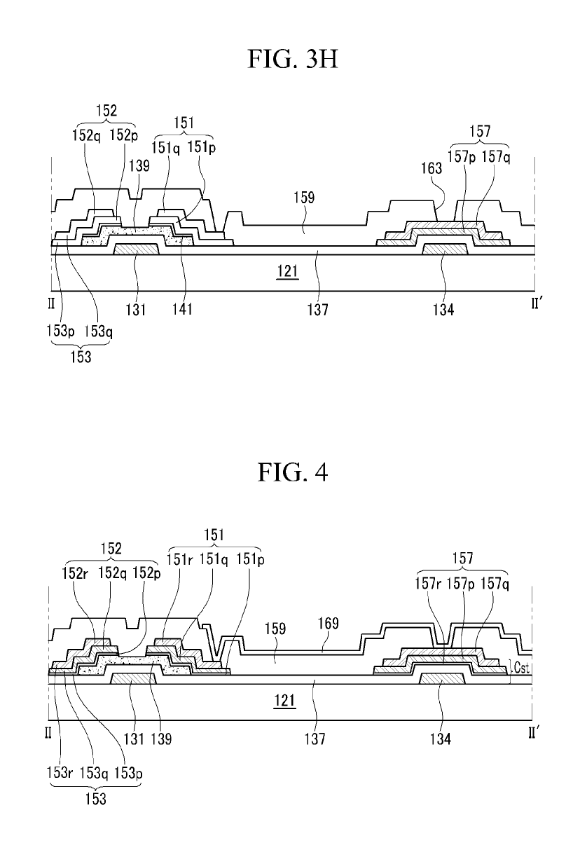

A manufacturing method of the TFT array panel shown in FIG. 1 and FIG. 2 according to an embodiment will be described in detail with reference to FIG. 3A to FIG. 3H along with FIG. 1 and FIG. 2. FIG. 3A to FIG. 3H are sectional views of the thin film transistor array panel shown in FIG. 1 and FIG. 2 in intermediate steps of a manufacturing method thereof.

Referring to FIG. 3A and FIG. 3B, a metal film 123 is deposited on a surface of an insulating substrate 121, and a photosensitive film 125 is coated on a surface of the metal film 123 opposite the insulating substrate 121. The photosensitive film 125 is exposed using a photo-mask including a plurality of transparent regions Al and a plurality of light blocking opaque regions A2 and developed to form photosensitive patterns 127 as shown in FIG. 3B. Thereafter, the metal film 123 is etched using the photosensitive patterns 127 as an etching mask to form a plurality of gate lines 133 including a plurality of gate electrodes 131 and a plurality of gate pads 135, and a plurality of storage electrode lines 134. In FIG. 3A, TFT region T and pixel area P are shown in cross-section along II-II′.

Next, a gate insulating layer 137 is formed on the surface of the insulating substrate 121 having the gate electrodes 131 and storage electrode line 134, an intrinsic a-Si layer (not shown) disposed on a surface of the gate insulating layer 137 opposite the insulating substrate 121, and an extrinsic a-Si layer (not shown) disposed on a surface of the intrinsic a-Si layer opposite gate insulating layer 137 are sequentially deposited, and then the extrinsic a-Si layer and the intrinsic a-Si layer are patterned by photolithography and etching to form a plurality of semiconductor layers 139 and a plurality of extrinsic semiconductor layers of ohmic contact layers 141 over the gate lines 133 as shown in FIG. 3C.

Next, a plurality of data lines 153 including a plurality of source electrodes 152 and a plurality of data pads 155, a plurality of drain electrodes 151, and a plurality of storage electrodes 157 are formed, and the channels 165 over the semiconductor layers 139 are exposed as shown in FIG. 3D to FIG. 3G. Now, this process will be described in detail with reference to FIG. 3D to FIG. 3G.

Firstly, a lower metal layer 143 including titanium or titanium nitride is deposited on a surface of the gate insulating layer 137, having the ohmic contact layers 141 opposite the insulating substrate 121, and an upper metal layer 145 including copper is deposited on a surface of the lower metal layer 143 opposite the gate insulating layer 137, sequentially deposited on the insulating substrate 121 as shown in FIG. 3D. Next, as shown in FIG. 3E and FIG. 3F, a photosensitive film 128 is coated on a surface of the upper metal layer 145 opposite lower metal layer 143, and then the photosensitive film 128 is exposed using a photo-mask Ml including a plurality of transparent regions G1 and a plurality of light blocking opaque regions G2 and developed to form a plurality of photosensitive patterns 129, and thereafter the upper metal layer 145 is wet-etched and the lower metal layer 143 is dry-etched using the photosensitive patterns 129 as an etching mask to form a plurality of data lines 153, a plurality of drain electrodes 151, and a plurality of storage electrodes 157 having a double-layered structure each including, respectively, a lower layer 153p, 151p, and 157p including titanium and an upper layer 153q, 151q, and 157q. Here, the doped semiconductor layers disposed on the channel regions of the TFT are also removed during dry-etching of the lower metal layer 143 such that the ohmic contact layers 141 are completed and the channel 165 of the TFT is formed. Then, the photosensitive patterns 129 are removed by ashing as shown in FIG. 3G.

In the know manufacturing method, a double-layered wire including a lower layer including titanium and an upper layer including copper may be patterned by wet-etching using an etchant of hydrogen peroxide (H₂O₂). However, when hydrogen peroxide (H₂O₂) is used as an etchant, undesired explosion or environmental contamination may occur. Accordingly, the use of hydrogen peroxide (H₂O₂) in a wet-etching process as an etchant is being reduced in favor of other less hazardous etchants. Meanwhile, it is known that the lower layer including titanium is difficult to pattern by wet-etching when not using an etchant of hydrogen peroxide (H₂O₂), while the upper layer including copper may be patterned by wet-etching when not using an etchant of hydrogen peroxide (H₂O₂). Accordingly, it is difficult to form a wire having a double-layered structure including a lower layer including titanium and an upper layer including copper by wet-etching when a hydrogen peroxide (H₂O₂) etchant is not used.

However, the thin film transistor array panel includes the data line 153 and the drain electrode 151 having a double-layered structure of a lower layer 153p and 151p including titanium and an upper layer 153q and 151q including copper, and the upper layer 153q and 151q including copper is wet-etched and the lower layer 153p and 151p including titanium is dry-etched, respectively. Accordingly, the upper layer 153q and 151q and the lower layer 153p and 151p may be readily patterned.

As described above, the upper layer 153q and 151q including copper is wet-etched and the lower layer 153p and 151p including titanium is dry-etched, respectively, such that planar edges of the lower layer 153p and 151p protrude from planar edges of the upper layer 153q and 151q. The protruding portions may have a width of about 0.4 μm to about 0.9 μm, and more preferably about 0.59 μm to about 0.85 μm.

Next, as shown in FIG. 3H, a passivation layer 159 is deposited on a surface of the gate insulating layer having the data lines 153, source electrodes 152, and drain electrodes 151, and is patterned by photolithography similar to the processes described hereinabove, and etched to form plurality of contact holes 161 and 163 exposing portions of the drain electrode 151 and the storage electrode 157, respectively.

Finally, a plurality of pixel electrodes 169 connected to the drain electrodes 151 and the storage electrodes 157 through the contact holes 161 and 163, respectively, are formed on a surface of the passivation layer 159 opposite the gate insulating layer 137, as shown in FIG. 2.

As described above, the thin film transistor array panel includes the data line 153 and the drain electrode 151 having a double-layered structure of a lower layer 153p and 151p including titanium and an upper layer 153q and 151q including copper, and the upper layers 153q and 151q including copper are wet-etched and the lower layers 153p and 151p including titanium are dry-etched, respectively. Accordingly, the upper layer 153q and 151q and the lower layer 153p and 151p may be readily patterned.

A thin film transistor array panel according to another embodiment will be described in detail with reference to FIG. 1 and FIG. 4. FIG. 4 is a layout view of a thin film transistor array panel according to an embodiment.

As shown in FIG. 1 and FIG. 4, a layered structure of a TFT array panel is substantially the same as that shown in FIG. 1 and FIG. 2.

Unlike the TFT array panel shown in FIG. 1 and FIG. 2, the data line 153 and the drain electrode 151 in FIG. 4 have a triple-layered structure of a lower layer 153p and 151p including titanium (Ti), a middle layer 153q and 151q including titanium nitride (TiNx) disposed on the lower layers 153p and 151p, and an upper layer 153r and 151r including copper disposed on the middle layers 153q and 151q opposite the lower layers 153p and 151p. In addition, also in FIG. 4, the ohmic contact layer 141 between the semiconductor layer 139, and the data line 153 and the drain electrode 151, (see FIG. 1) may be omitted. Here, the lower layer 153p and 151p made of titanium (Ti) of the data line 153 and the drain electrode 151 functions as the ohmic contact layer, and the middle layer 153q and 151q including titanium nitride (TiNx) functions as a barrier layer for blocking the diffusion of the upper layer 153r and 151r made of copper.

In the thin film transistor array panel, the lower layer 153p and 151p of the data lines 153 and the drain electrodes 151 may be formed by dry-etching, and the middle layer 153q and 151q and the upper layer 153r and 151r of the data lines 153 and the drain electrodes 151 may be formed by wet-etching. Accordingly, planar edges of the lower layer 153p and 151p and the middle layer 153q and 151q of the data line 153 and drain electrode 151 have a protruding portion protruding from under the planar edges of the upper layer 153r and 151r, and the protruding portion of the lower layer 153p and 151p and the middle layer 153q and 151q has a width of about 0.4 μm to about 0.9 μm, and more specifically about 0.59 μm to about 0.85 μm.

Many characteristics of the TFT array panel shown in FIG. 1 and FIG. 2 and the manufacturing method thereof shown in FIG. 3A to FIG. 3H can be applied to the TFT array panel shown in FIG. 1 and FIG. 4.

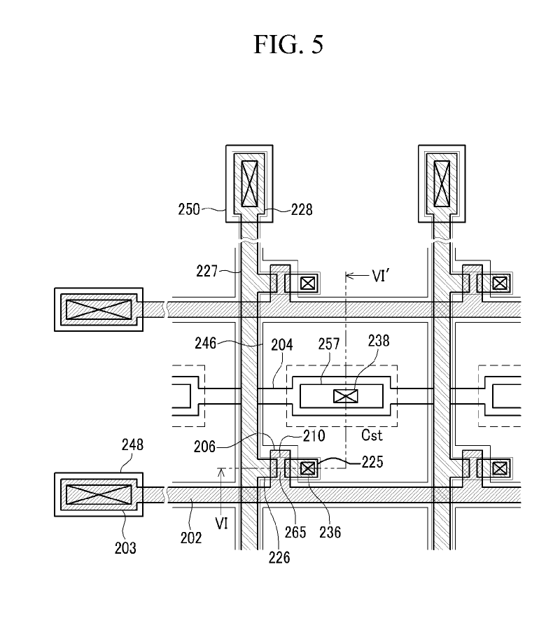

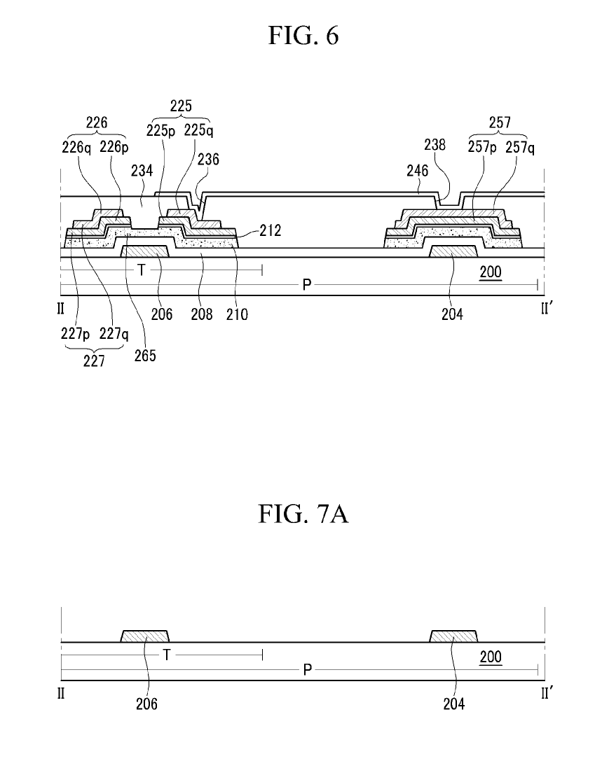

Now, a thin film transistor array panel according to another embodiment will be described in detail with reference to FIG. 5 and FIG. 6. FIG. 5 is a layout view of a thin film transistor array panel according to another embodiment, and FIG. 6 is a sectional view of the thin film transistor array panel shown in FIG. 5 taken along the lines VI-VI′.

As shown in FIG. 5 and FIG. 6, a layered structure of a TFT array panel is substantially the same as that shown in FIG. 1 and FIG. 2 with any differences described in the following description.

A plurality of gate lines 202 including a plurality of gate electrodes 206 and a plurality of gate pads 203, and a plurality of storage electrode lines 204 are formed on an insulating substrate 200. The gate pad 203 is connected to an auxiliary gate pad 248 disposed on a surface of the gate pad 203, through a contact hole. A gate insulating layer 208 is formed on a surface of the insulating substrate 200 having the gate lines 202 and the storage electrode lines 204. A plurality of semiconductor layers 210 disposed on the gate insulating layer 208 opposite the insulating substrate 200, a plurality of ohmic contact layers 212 disposed on the semiconductor layers 210 opposite gate insulating layer 208, a plurality of data lines 227 and drain electrodes 225 disposed on a surface of the ohmic contact layers 212 opposite the semiconductor layers 210, and a plurality of storage electrodes 257 disposed on a surface of ohmic contact layer 212 are sequentially formed on the gate insulating layer 208. A passivation layer 234 is disposed on a surface of the data lines 227, drain electrodes 225, and storage electrodes 257, where a plurality of contact holes 236 and 238 are formed in the passivation layer 234 over the plurality of data lines 227 and drain electrodes 225. A plurality of storage electrodes 257 and exposed portions of the semiconductor layers 210, and a plurality of pixel electrodes 246 connected to the drain electrodes 225 and the storage electrodes 257 through the contact holes 236 and 238 are formed on the passivation layer 234.

The data lines 227 and the drain electrodes 225 have a dual-layered structure respectively including lower layers 227p and 225p and upper layers 227q and 225q. The lower layers 227p and 225p may be made of titanium (Ti) or titanium nitride (TiNx), and the upper layer 227q and 225q may be made of copper (Cu). The lower layers 227p and 225p function barrier layers for blocking diffusion of the upper layers 227q and 225q made of copper. Here, the lower layer 227p and 225p of the data lines 227 and the drain electrodes 225 may have a double-layered structure having a lower layer made of titanium (Ti) and an upper layer made of titanium nitride (TiNx).

In the thin film transistor array panel, the lower layer 227p and 225p of the data lines 227 and the drain electrodes 225 may be formed by dry-etching of precursor metal layer(s) to the data lines 227 and drain electrodes 225 and the upper layer 227q and 225q of the data lines 227 and the drain electrodes 225 may be formed by wet-etching of precursor metal layer(s). Accordingly, planar edges of the lower layer 227p and 225p of the data lines 227 and the drain electrodes 225 have a protruding portion protruding more than the planar edges of the upper layer 227q and 225q, and the protruding portion of the lower layer 227p and 225p has a width of about 0.4 μm to about 0.9 μm, and more specifically about 0.59 μm to about 0.85 μm.

Unlike the TFT array panel shown in FIG. 1 and FIG. 2, the semiconductor layers 210 and the ohmic contact layers 212 are disposed under the data lines 227, the drain electrodes 225, and the storage electrodes 257 except for the region under the channel 265 of the TFT. In addition, the data lines 227, the drain electrodes 225, and the storage electrodes 257 have substantially the same planar shape as that of the semiconductor layers 210 and the ohmic contact layers 212 except for channel 265 of the TFT, and particularly, the lower layer 227p, 225p, and 257p of the data lines 227, the drain electrodes 225, and the storage electrodes 257 have the same planar shape as that of the ohmic contact layers 212.

As described above, the lower layer 227p and 225p of the data lines 227 and the drain electrodes 225 may be formed by dry-etching a lower metal precursor layer for the data lines 227 and the drain electrodes 225, and the upper layer 227q and 225q of the data lines 227 and the drain electrodes 225 may be formed by wet-etching an upper metal precursor layer. In addition, the lower layer 227p and 225p including titanium functions a barrier layer for blocking the diffusion of the upper layer 227q and 225q made of copper so that performance degradation of the thin film transistor caused by the diffusion of copper may be prevented.

In another embodiment, the data lines 227 and the drain electrodes 225 may have a triple-layered structure of a lower layer including titanium (Ti), a middle layer disposed on a surface of the lower layer including titanium nitride (TiNx), and an upper layer disposed on a surface of the middle layer opposite the lower layer, and including copper. In addition, the ohmic contact layer 212 between the semiconductor layer 210, and the data line 227 and the drain electrode 225, may be omitted. Here, the lower layer including titanium (Ti) of the data line 227 and the drain electrode 225 functions as the ohmic contact layer, and the middle layer including titanium nitride (TiNx) functions as a barrier layer for blocking the diffusion of the upper layer including copper.

Many characteristics of the TFT array panel shown in FIG. 1 and FIG. 2 can be applied to the TFT array panel shown in FIG. 5 and FIG. 6.

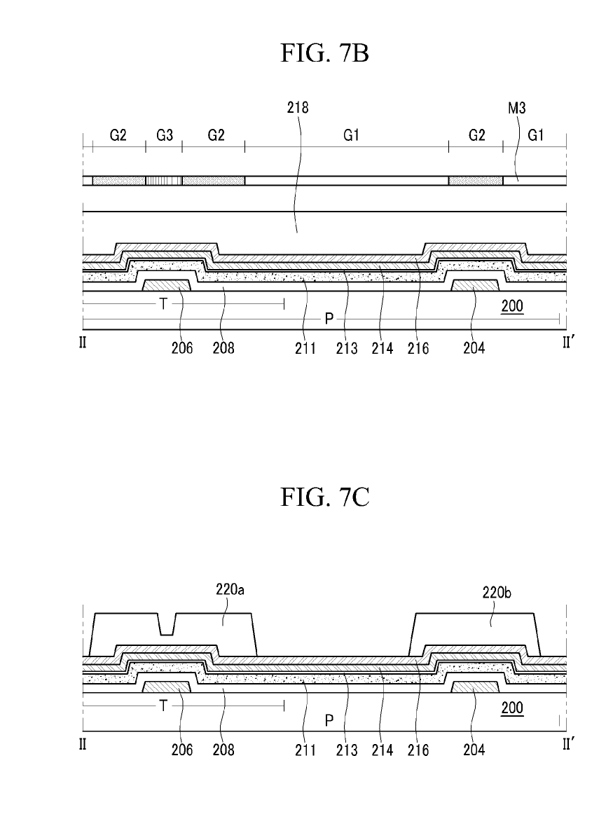

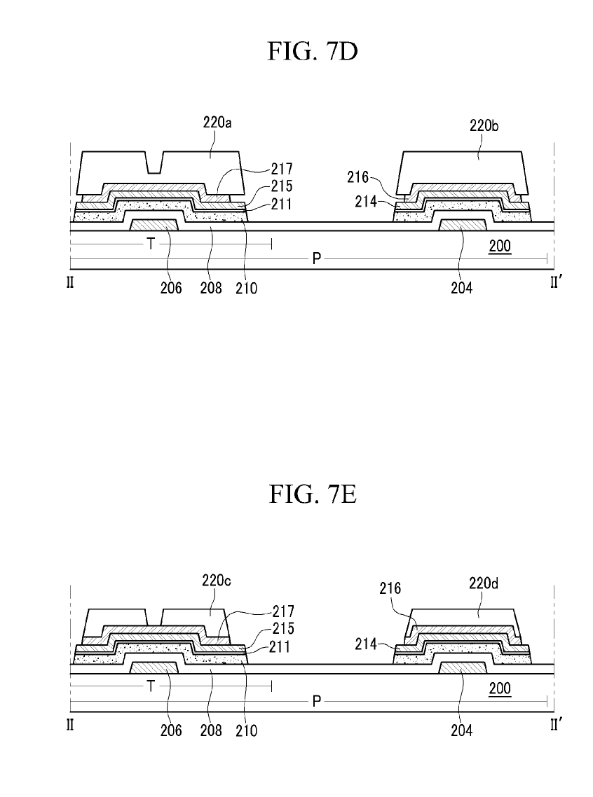

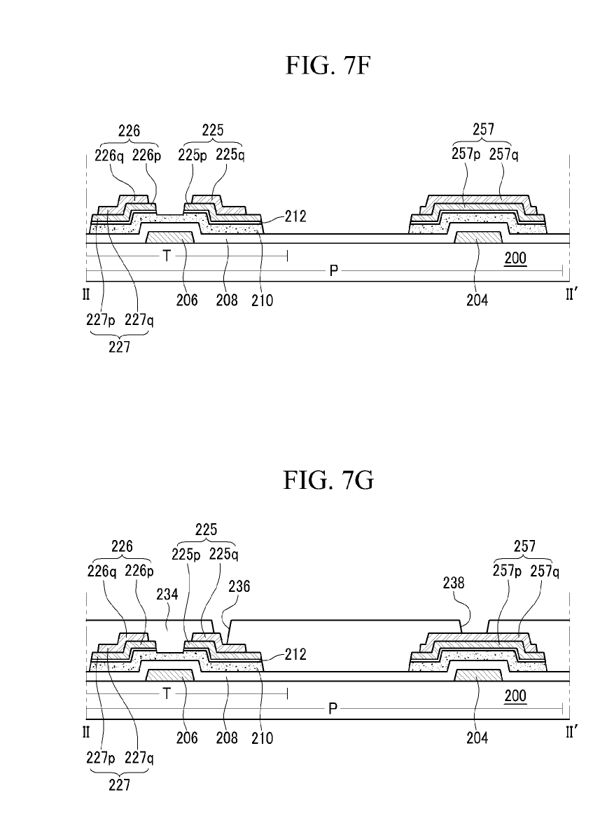

A manufacturing method of the TFT array panel shown in FIG. 5 and FIG. 6 will be described in detail with reference to FIG. 7A to FIG. 7G along with FIG. 5 and FIG. 6. FIG. 7A to FIG. 7G are sectional views of the thin film transistor array panel shown in FIG. 5 and FIG. 6 in intermediate steps of a manufacturing method thereof according to an embodiment.

Referring to FIG. 7A, a plurality of gate lines 202 including a plurality of gate electrodes 206 and a plurality of gate pads 203 and a plurality of storage electrode lines 204 are formed on a surface of an insulating substrate 200.

Next, as shown in FIG. 7B, a gate insulating layer 208 is deposited on a surface of the insulating substrate 200, an intrinsic a-Si layer 211 is deposited on a surface of the gate insulating layer 208 opposite the insulating substrate 200, and an extrinsic a-Si layer 213 is deposited on a surface of the intrinsic a-Si layer 211, and on the gate lines 202 and the storage electrode lines 204. A lower metal layer 214, deposited on a surface of the extrinsic a-Si layer 213 opposite the intrinsic a-Si layer 211, and an upper metal layer 216 deposited on a surface of the lower metal layer 214 opposite the extrinsic a-Si layer 213, are each sequentially deposited. Here, the lower metal layer 214 includes titanium or titanium nitride, and the upper metal layer 216 includes copper. Next, a photosensitive layer 218 is coated on a surface of the upper metal layer 216 and then the photosensitive film 218 is exposed using a photo-mask M3 having a plurality of transparent regions G1, a plurality of light blocking opaque regions G2, and a plurality of transparent regions G3 and developed to form a plurality of photosensitive patterns 220a and 220b, as shown in FIG. 7C. Here, the photosensitive layer patterns 220a and 220b have a position-dependent thickness, and the photosensitive layer patterns 220a and 220b include a plurality of first portions and a plurality of second portions having a lesser thickness than the first portions. The first portions are located on the data line areas under which the data lines 227, the drain electrodes 225, and the storage electrodes 257 are formed, and the second portions are located over the channel area. The photosensitive layer patterns 220a have both the first (thicker) portions and the second (thinner) portions, and the photosensitive layer patterns 220b have only the thicker first portions.

Next, the upper metal layer 216 is wet-etched, and the lower metal layer 214, the extrinsic a-Si layer 213, and the intrinsic a-Si layer 211 are each dry-etched using the photosensitive patterns 220a and 220b to form lower data patterns 215 and upper data patterns 217 as well as extrinsic a-Si patterns 211 and the semiconductor layers 210 as shown in FIG. 7D.

Referring to FIG. 7E, ashing is performed on the photosensitive layer patterns 220a and 220b such that the photosensitive patterns 220a and 220b are partially removed to form photosensitive layer patterns 220c and 220d. Here, the second portions located on the channel areas are completely removed such that the upper data patterns 217 of the channel areas are exposed. The upper data patterns 217 of the channel areas are wet-etched using the photosensitive layer patterns 220c and 220d as an etching mask to remove the upper data patterns 217 of the channel areas. Thereafter, the lower data patterns 215 and the extrinsic a-Si patterns 211 of the channel areas are dry-etched using the photosensitive layer patterns 220c and 220d as an etching mask and removed such that the data lines 227, the drain electrodes 225, and the storage electrodes 257 including the lower layers 227p, 225p, and 257p and the upper layers 227q, 225q, and 257q are formed with channel 265 located between the data lines 227 and the drain electrodes 225, and the semiconductor layers 210 and the ohmic contact layers 212 are completed. Finally, the photosensitive layer patterns 220c and 220d are removed as shown in FIG. 7F. As described above, the lower data patterns 215, the extrinsic a-Si patterns 211, and the semiconductor layers 210 are formed using the same photosensitive layer patterns 220c and 220d, and thereby the data lines 227, the drain electrodes 225, and the storage electrodes 257 have substantially the same planar shape as that of the semiconductor layers 210 and the ohmic contact layers 212 except for channel 265 of the TFT, and particularly, the lower layer 227p, 225p, and 257p of the data lines 227, the drain electrodes 225, and the storage electrodes 257 has the same planar shape as that of the ohmic contact layers 212. In addition, the data lines 227, the drain electrodes 225, and the storage electrodes 257, and the semiconductor layers 210 and the ohmic contact layers 212, are formed using one lithography step, thereby reducing the manufacturing time and cost.

Next, a passivation layer 234 is disposed on a surface of the gate insulation layer 208 having the source electrode 226, data line 227, drain electrode 225, and storage electrode 257, where the passivation layer 234 has a plurality of contact holes 236 and 238 formed as shown in FIG. 7G.

Finally, a plurality of pixel electrodes 246 disposed on a surface of the passivation layer 234 and connected to the drain electrodes 225 and the storage electrodes 257 through the contact holes 236 and 238, respectively, are formed on the passivation layer 234 as shown in FIG. 6.

Many characteristics of the manufacturing method of the TFT array panel shown in FIG. 3A to FIG. 3H can be applied to the manufacturing method of the TFT array panel shown in FIG. 7A to FIG. 7G.

As described above, in the thin film transistor array panel, the data lines 227 and the drain electrodes 225 have a dual-layered structure including the lower layer 227p and 225p including titanium (Ti) and the upper layer 227q and 225q made of copper (Cu), and the precursor metal layer to the lower layer 227p and 225p including titanium (Ti) is dry-etched along with the semiconductor layer 210 and the ohmic contact layer 212, and the precursor metal layer to the upper layer 227q and 225q made of copper (Cu) is wet-etched. Accordingly, the layers may be readily patterned.

In the thin film transistor array panel, the lower layer 227p and 225p of the data lines 227 and the drain electrodes 225 may be formed by dry-etching a metal precursor layer, and the upper layer 227q and 225q of the data lines 227 and the drain electrodes 225 may be formed by wet-etching a metal precursor layer. Accordingly, planar edges of the lower layer 227p and 225p of the data lines 227 and the drain electrodes 225 have a protruding portion protruding that protrudes more than planar edges of the upper layer 227q and 225q, and the protruding portion of the lower layer 227p and 225p may have a width of about 0.4 μm to about 0.9 μm, and more specifically about 0.59 μm to about 0.85 μm.

In the above embodiment, while the thin film transistor array panels used for a liquid crystal display (“LCD:) were described, the present invention can be employed to any other thin film transistor array panels used for a flat panel display, including an organic light emitting diode display (“OLED”) and an electrophoretic display.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel comprising:
a gate line formed on a substrate and including a gate electrode;
a semiconductor layer formed on the gate electrode;
a data line formed on the semiconductor layer, insulatedly intersecting the gate line, and comprising a source electrode disposed on the gate electrode;
a drain electrode separated from the source electrode by a channel exposing a portion of the semiconductor layer, and disposed on the gate electrode and formed from the same layer as the data line;
a passivation layer formed on the data line and the drain electrode and having a first contact hole exposing a portion of the drain electrode; and
a pixel electrode formed on the passivation layer and contacting the drain electrode through the first contact hole,
wherein the data line and the drain electrode each comprise a first layer and a second layer formed on the first layer, and a planar edge of the first layers protrude from a corresponding planar edge of the second layers.

2. The thin film transistor array panel of claim 1, wherein the second layers of the data line and drain electrode comprise copper.

3. The thin film transistor array panel of claim 1, wherein the protruding portion of the first layer has a width of about 0.4 μm to about 0.9 μm.

4. The thin film transistor array panel of claim 3, wherein the protruding portion of the first layer has a width of about 0.59 μm to about 0.85 μm.

5. The thin film transistor array panel of claim 1, wherein a gap between the second layers of the source electrode and the drain electrode is larger than that between the first layers of the source electrode and the drain electrode.

6. The thin film transistor array panel of claim 1, wherein the semiconductor layer has substantially the same planar shape as that of the data line and the drain electrode except that the semiconductor layer is not bisected by the channel.

7. The thin film transistor array panel of claim 6, wherein a gap across the channel and between the second layers of the source electrode and the drain electrode is larger than a gap across the channel between the first layers of the source electrode and the drain electrode.

8. The thin film transistor array panel of claim 7, wherein the first layer of the data line and drain electrode has a double-layered structure having a lower layer comprising titanium (Ti) and an upper layer comprising titanium nitride (TiNx) and formed on the lower layer.

9. The thin film transistor array panel of claim 7, further comprising a storage electrode line separated from the gate line and extending parallel to the gate line,
wherein the storage electrode line overlaps the pixel electrode to form a storage capacitor.

10. The thin film transistor array panel of claim 7, further comprising
a storage electrode formed of the same layer as the data line,
wherein the passivation layer has a second contact hole exposing a portion of the storage electrode line, and
wherein the storage electrode is connected to the pixel electrode through the second contact hole and overlaps the storage electrode line to form a storage capacitor.

11. The thin film transistor array panel of claim 10, wherein the storage electrode line comprises a first portion overlapping the storage electrode and a second portion not overlapping the storage electrode, and the first portion has a larger surface area than that of the second portion.

12. The thin film transistor array panel of claim 2, wherein the first layer of the data line and drain electrode comprises titanium (Ti), titanium nitride (TiNx), or both Ti and TiNx.

13. The thin film transistor array panel of claim 12, wherein the first layer of the data line and drain electrode has a double-layered structure having a lower layer comprising titanium (Ti) and an upper layer comprising titanium nitride (TiNx) and formed on a surface of the lower layer.

14. The thin film transistor array panel of claim 1, wherein the first layers of the data line and drain electrode are formed by dry-etching a first metal layer, and the second layer of the data line and drain electrode are formed by wet-etching a second metal layer.

15. A manufacturing method of a thin film transistor array panel, comprising:
forming a gate line comprising a gate electrode on a substrate;
forming a gate insulating layer on the substrate having the gate line;
forming a semiconductor layer on the gate insulating layer;
forming a data line insulatedly intersecting the gate line and comprising a source electrode and a drain electrode each disposed on the semiconductor layer opposite the gate electrode, the drain electrode separated from the source electrode by a channel exposing a portion of the semiconductor layer;
forming a passivation layer over the source electrode and drain electrode, the passivation layer having a first contact hole exposing a portion of the drain electrode; and
forming a pixel electrode on the passivation layer, the pixel electrode contacting the drain electrode through the first contact hole on the passivation layer,
wherein the data line and the drain electrode each comprise a first layer and a second layer formed on the first layer, and
wherein the first layer of the data line and drain electrode is formed by dry-etching, and the second layer is formed by wet-etching.

16. The manufacturing method of claim 15, wherein a planar edge of the first layers of the data line and drain electrode protrude from beneath a corresponding planar edge of the second layers of the data line and drain electrode.

17. The manufacturing method of claim 15, wherein the forming of the data line and the drain electrode comprises:
depositing a first metal layer on the semiconductor layer;
depositing a second metal layer on the first metal layer;
forming a photosensitive layer pattern on the second metal layer;forming the second layer of the data line and drain electrodes by wet-etching the second metal layer with the photosensitive layer pattern as a mask; and
forming the first layer of the data line and drain electrodes by dry-etching the first metal layer with the photosensitive layer pattern and the second layer of the data line and drain electrodes as a mask.

18. The manufacturing method of claim 15, wherein the second layer of the data line and drain electrodes comprises copper.

19. The manufacturing method of claim 18, wherein the first layer of the data line and drain electrodes comprises titanium (Ti) or titanium nitride (TiNx), or both Ti and TiNx.

20. The manufacturing method of claim 18, wherein the first layer of the data line and drain electrodes has a double-layered structure having a lower layer comprising titanium (Ti) and an upper layer comprising titanium nitride (TiNx) and formed on the lower layer.

21. The manufacturing method of claim 16, wherein the protruding portion of the first layer has a width of about 0.4 μm to about 0.9 μm.

22. The manufacturing method of claim 21, wherein the protruding portion of the first layer has a width of about 0.59 μm to about 0.85 μm.

23. The manufacturing method of claim 15, wherein the forming of the semiconductor layer and the forming of the data line and the drain electrode are performed simultaneously, and
wherein the forming of the semiconductor layer, the data line, and drain electrode comprises:
depositing a semiconductor film on the gate insulating layer;
depositing a first metal layer on the semiconductor film;
depositing a second metal layer on the first metal layer;
forming a first photosensitive layer pattern on the second metal layer;
patterning the second metal layer by wet-etching the second metal layer with the first photosensitive layer pattern as a mask;
patterning the first metal layer and forming the semiconductor layer by dry etching the first metal layer and the semiconductor film with the patterned second metal layer as a mask;
ashing a portion of the first photosensitive layer patterns to form a second photosensitive layer patterns exposing the channel region;
wet-etching the second metal layer with the second photosensitive layer pattern as a mask to remove the second metal layer on the channel regions to form the second layer of the data line and the drain electrode;
dry-etching the first metal layer with the second photosensitive layer pattern and the second layer of the data line and the drain electrode as a mask to remove the first metal layer in the channel region to form the first layer of the data line and the drain electrode; and
removing the second photosensitive layer pattern.

24. The manufacturing method of claim 23, wherein the second metal layer comprises copper.

25. The manufacturing method of claim 24, wherein the first metal layer comprises titanium (Ti), titanium nitride (TiNx), or both Ti and TiNx.

26. The manufacturing method of claim 24, wherein the first layers of the data line and the drain electrode have a double-layered structure having a lower layer comprising titanium (Ti) and an upper layer comprising titanium nitride (TiNx) and formed on the lower layer.
